(19) United States
(12) Patent Application Publication
(10) Pub. No.: US 2006/0049465 A1
(43) Pub. Date: Mar. 9, 2006

(54) Power semiconductor device for preventing punchthrough and manufacturing method thereof

(75) Inventor: Jong-Min Kim, Incheon City (KR)

Correspondence Address: BIRCH STEWART KOLASCH & BIRCH, PO BOX 747, FALLS CHURCH, VA, 22040-0747, US

(73) Assignee: LITE-ON SEMICONDUCTOR CORP.

(21) Appl. No.: 11/202,176

(22) Filed: Aug. 12, 2005

(30) Foreign Application Priority Data
Sep. 9, 2004 (KR) 10-2004-0072073

(51) Int. Cl. H01L 29/76

(52) U.S. Cl. 257/372

(57) ABSTRACT

This invention presents a power semiconductor for preventing punchthrough in the channel area. For this purpose, the invention presents a power semiconductor possessing a high concentration substrate area of conduction type 1; a primary epitaxial area of conduction type 1, formed in low concentration on top of the drain area; a secondary epitaxial area of conduction type 1, formed in medium concentration on top of the primary epitaxial area and with a doping profile that is actually uniform over the thickness; multiple secondary body areas of conduction type 2, formed within the secondary epitaxial area; and two source areas of conduction type 1, formed in high concentration along both edges of the body areas.

### BACKGROUND OF THE INVENTION

1. Field of the Invention

This invention pertains to the power semiconductor and its manufacturing method. In detail, it presents a power semiconductor featuring high breakdown voltage as a means to prevent punchthrough, and it's the method for manufacturing such semiconductors.

2. Description of Related Art

It is important in power semiconductors to set the low on-resistance between the drain and the source as to allow electrical or hole mobility in the channel even under low voltage conditions. It is well documented that the most influential factor of on-resistance is the resistance on top of the epitaxial layer, which is formed in the substrate. This upper section of the epitaxial layer is called the JFET, or Junction Field Effect Transistor. A common method of lowering the overall on-resistance by adjusting the resistance level at JFET is by implanting accelerated n-type impurity ions on the JFET and then diffusing the impurity. Under this method, the concentration profile of impurity within the JFET exhibits a Gaussian distribution, where the impurity concentration gradually lowers, going deeper into the JFET. This is because impurity diffusion starts from the JFET surface and gradually travels inward.

Power semiconductors bearing a Gaussian distribution density profile as the result of ion implantation exhibit a low breakdown voltage. Specifically, this is caused by improper p-type body formation within the epitaxial layer after implantation with a high dose of impurity ions. In other words, because the body area is of opposite conductivity than the implanted n-type impurity ions, the n-type impurity ions reverse p-type conductivity of the body area and either lower the density along the other edge of the body area or else prevent p-type impurities from forming at all. The outer edge of the body area is where the channel forms. With lowered density in this area, the power semiconductor is more susceptible to the punchthrough effect.

Increasing the body area concentration is one viable option to prevent the punchthrough effect, but this should be avoided since it concurrently increases the semiconductor's turn-on voltage. Impressing reverse bias has been long considered an seriously severe problem because it induces the punchthrough effect at the channel area and lowers the breakdown voltage.

Accordingly, as discussed above, the prior art still has some drawbacks that could be improved. The present invention aims to resolve the drawbacks in the prior art.

### SUMMARY OF THE INVENTION

As a solution to the problem presented above, this invention retains the objective of presenting a power semiconductor device with a uniform concentration profile, as opposed to a Gaussian distribution profile, at the JFET area for lowered resistance, and the manufacturing method thereof.

In addition, the invention also retains the objective of presenting a power semiconductor in which the designer is able to freely choose the JFET thickness within the epitaxial layer, and the manufacturing method thereof.

Other objectives of the invention shall be described in detail within the following descriptions and claims sections.

Numerous additional features, benefits and details of the present invention are described in the detailed description, which follows.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 illustrates a practical application example of the power MOSFET (Metal Oxide Silicon Field Effect Transistor) as per this invention.

FIG. 2 (a) to FIG. 2 (e) illustrates the sequence of epitaxial area manufacturing in the power MOSFET as per this invention.

FIG. 3 illustrates a MOSFET possessing a secondary epitaxial area that is thicker (d3) than the example shown in FIG. 2 (e).

FIG. 4 (a) and FIG. 4 (b) are graphs that illustrate doping density distribution and electrical field intensity over depth in a thin secondary epitaxial area design.

FIG. 5 (a) and FIG. 5 (b) are graphs that illustrate doping density distribution and electrical field intensity over depth in a thick secondary epitaxial area design.

FIG. 6 illustrates a power MOSFET that has been produced using the conventional method of ion implantation and diffusion.

### DESCRIPTION OF PREFERRED EMBODIMENTS

For the above objectives, this invention presents an anti-punchthrough power semiconductor possessing a high concentration drain area of conduction type 1; a primary substrate area of conduction type 1, formed in low density on top of the drain area; a secondary epitaxial area of conduction type 1, formed in medium concentration on top of the primary epitaxial area and with a density profile that is actually uniform over the thickness; with multiple secondary body areas of conduction type 2, formed within the secondary epitaxial area; and two source areas of conduction type 1, formed in high density along two edges of the body areas.

For the above objectives, this invention also presents an anti-punchthrough power semiconductor manufacturing method consisting of a stage in which the high density drain area of conduction type 1 is formed, a stage in which the primary epitaxial area of conduction type 1 formed on top of the high concentration substrate area is grown in low concentration using epitaxy, a stage in which the secondary epitaxial area of conduction type 1, formed on top of the primary epitaxial area is grown in medium density using epitaxy; a stage in which multiple body areas of conduction type 2 are formed within the secondary epitaxial area; and a stage in which the two source areas of conduction type 1 are formed in high density along the two edges of the body areas.

Conduction type 1 is n-type, and conduction type 2 is p-type.

The semiconductor can be a MOS field effect transistor.

The body areas should include a primary body area of high concentration and a secondary body area of low concentration, formed along the outer edge of the primary body area. Here, the body areas can be formed at a certain section of the primary epitaxial area.

The power semiconductor as per this invention can further include gate dielectrics located on top of the second epitaxial area and between the body areas, gate electrodes that impress electrical voltage on the gate areas, source electrodes that electrically connect with the source areas, and drain electrodes that electrically connect with the drain areas.

This invention, therefore, is capable of forming the p-type body areas with greater stability and under less influence from concentration changes, and thereby prevents punchthrough effect at the channel.

Following is a more in-depth description of the invention with references to the attached diagrams. In the practical application examples of this invention, the semiconductor is assumed to be a MOS field effect transistor (hereinafter referred to as MOSFET).

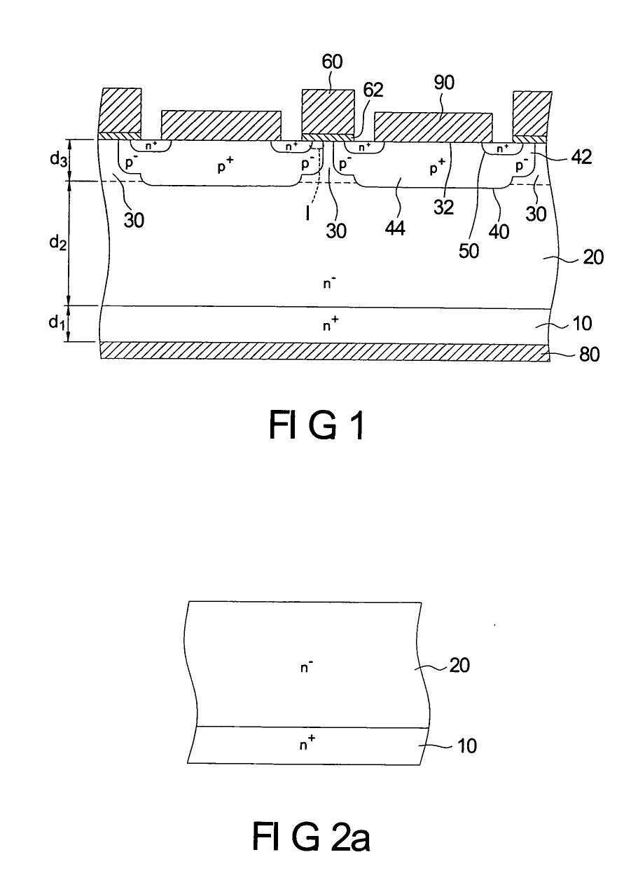

FIG. 1 illustrates a practical application example of the power MOSFET as per this invention.

The power MOSFET in this practical application example of the invention consists of an n-type drain area (10) of conduction type 1; primary and secondary n-type epitaxial areas (20, 30) formed on top of the substrate area and through which electrical or hole can flow; and a p-type body area (40) of conduction type 2, formed on top of the epitaxial areas (20, 30). The body area consists of a primary body area (42), which has slightly lower density and is formed along the outer edge, and a secondary body area (44), which is formed within the primary body area (42). In the body area (40), an n-type source area (50) is formed slightly inwards from the primary body area (42). Furthermore, the power MOSFET as per one of this invention's practical application examples also includes source electrodes (90), drain electrodes (80), and gate electrodes (60). Here, the source electrode (90) is formed on the body area (40) so that it comes in partial contact with the source area (50), the drain electrode (80) is formed on one side of the substrate area (10), and the gate electrode (60) is formed with a gate electrode (62) on top of the area between where the channel is formed (I) and the body areas (40). Conduction type 1 in this example is n-type and conduction type 2 is p-type; however, it can be set as vice versa. Following is a detailed description of each of the components.

The drain area (10) includes an n-type (n+) semiconductor substrate of thickness d1. Formed on one side of the drain area (10) is a drain electrode (80) that electrically connects with the drain area (10).

The primary epitaxial area (20) is formed on the drain area (10) surface to where the drain electrode (80) is formed, with thickness of d2. The primary epitaxial area (20) is of an n-type (n−) and should be doped at sufficiently lower concentration than the substrate area (10) to ensure higher breakdown voltage.

The secondary epitaxial area (30) comes in contact with the primary epitaxial area (20) and is formed on top with thickness of d3. The secondary epitaxial area (30) is also of an n-type (n°) and is doped at lower density than the substrate area (10) but higher density than the primary epitaxial area (20). The MOSFET's on-resistance lowers as the secondary epitaxial area (30) becomes doped with higher concentration.

The body areas (40) are formed in multiples deeply the secondary epitaxial area (30), where each section is distanced apart at a specific interval to form npn transistor required for proper electrical or positive hole mobility. The designer determines the thickness of the body areas (40), but bottom sections of the body areas (40) are extended to the primary epitaxial area (20) in FIG. 1 because the body areas (40) are designed thicker than the secondary epitaxial area (30). The body areas (40) receive p-type doping, but as described above, it consists of a high-density (p+) body area (40) and a low-density (p−) body area. The low-density body area (42) is positioned along the outer edge, whereas the high-density body area (44) resides within the low-concentration body area(42). The high-density body area (44) serves to sustain avalanche breakdown, and the low-density body area (42) lowers the turn-on voltage.

The source area (50) is formed within the body area (40) at a specific distance inwards from its outer edge and doped to high n-type (n+) concentration. The source area (50) is doped at higher concentration than the primary and secondary epitaxial areas (20, 30). The secondary area (30), body area (40), and source area (50) form npn transistor, and the area close to the secondary epitaxial area's surface (32) located between the source area (50) and the body area's (40) outer edge operates as the channel area (I) when turn-on voltage is impressed.

The gate electrode (60), featuring the gate dielectric (62), is formed on top of the area between the body areas (40). This is also where the channel (I) is formed when turn-on voltage is impressed on the gate electrode (60).

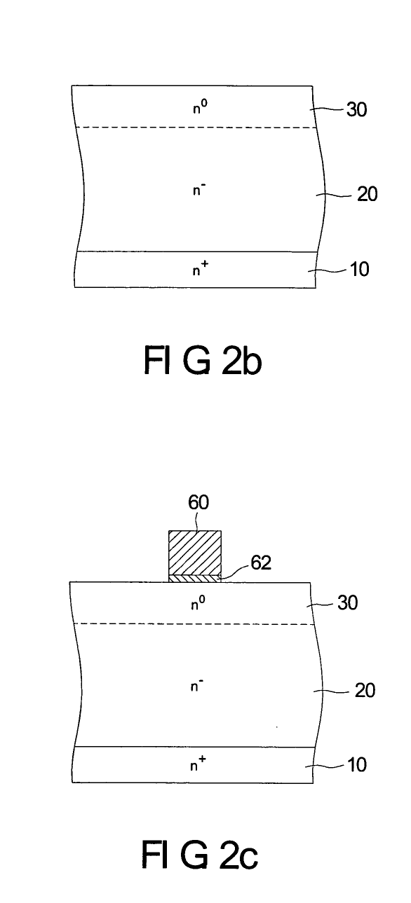

Referring to FIG. 2, the following describes the manufacturing method for the epitaxial area, which is designed to lower the resistance at the JFET.

FIG. 2 (a) to (e) illustrate the sequence of epitaxial and process manufacturing in the power MOSFET as per this invention.

As shown in FIG. 2 (a), a single crystal silicon layer is grown on top of the silicon wafer (10, substrate) from a reaction gas produced under a chemical reaction between trichlorosilane and hydrogen to form the primary epitaxial area (20). The silicon layer is formed on the surface of the silicon wafer by means of a chemical reaction. The reaction gas that is injected flows over the surface of the substrate (10) to form a boundary layer. The reaction gas then diffuses via the boundary layer, causing a chemical reaction that forms an epitaxial layer and subsequently the epitaxial area (20).

Continuing on, FIG. 2 (b) illustrates how impurities (dopants) are introduced to the reaction gas to change the low impurity (dopant) gas density (n−) to medium density (n°) in forming an epitaxial layer and subsequently the secondary epitaxial area (30). The secondary epitaxial layer (30) stops growing once it reaches the desired thickness. Adjusting the concentration of the impurity (dopant) can adjust the resistivity of the secondary epitaxial layer (30).

Following the formation of the two epitaxial areas (20, 30), the gate dielectric (62) and gate electrode (60) are photolithographically formed in sequence on top of the two epitaxial areas (20, 30) as shown in FIG. 2 (c).

Then, as shown in FIG. 2 (d), p-type impurity are introduced to the epitaxial areas (20, 30) to form high impurity concentration and low-impurity concentration body areas (40). Then high-concentration n-type impurity are introduced to form source areas (50) as shown in FIG. 2 (e).

Although not shown, the drain and source electrodes are subsequently formed following the above steps.

In this application example, the power MOSFET's on-resistance and breakdown voltage can be adjusted by varying the thickness of the primary (20) and secondary (30) epitaxial areas.

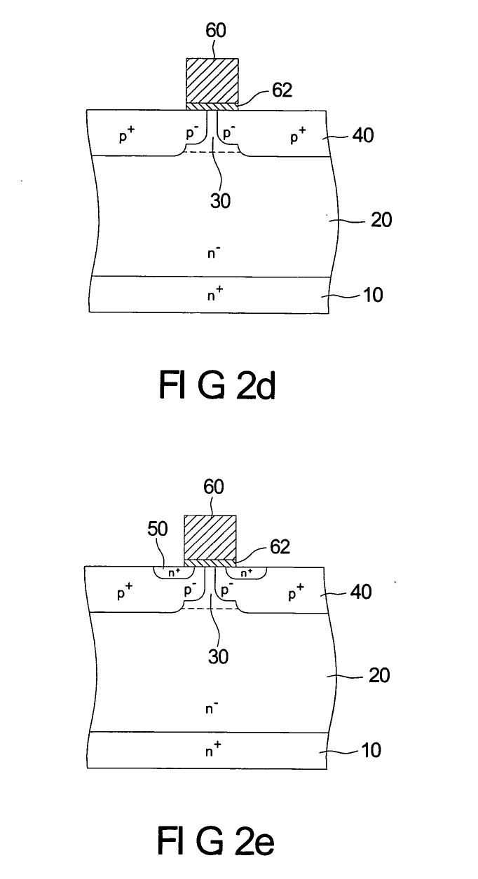

FIG. 3 illustrates a MOSFET possessing a secondary epitaxial area that is thicker (d3) than the example shown in FIG. 2 (e). The secondary epitaxial area is made thicker, and the primary epitaxial area is accordingly made thinner (d2). If the secondary epitaxial area were to be formed thickly as shown in FIG. 3, the thickness (d3) would exceed the body area (40) thickness and position it entirely within the secondary epitaxial area (30).

A thick secondary epitaxial area (30) formation lowers the on-resistance and breakdown voltage. Conversely, a thin secondary epitaxial area (30) formation as shown in FIG. 2 (e) increases the on-resistance and breakdown voltage. In other words, a thick design offers the benefit of lowering the on-resistance but also lowers the breakdown voltage, whereas a thin design offers the benefit of increasing the breakdown voltage but increas the on-resistance. The two designs are thereby said to have an inversely proportionate relationship, which allows the designer to factor in on-resistance and breakdown voltage values in determining the thickness of the two epitaxial areas (20, 30).

A power MOSFET manufactured as per this invention's application example has a greatly varying doping density profile at the JFET compared with the conventional ion implantation and diffusion method-based MOSFETs. The following describes this difference.

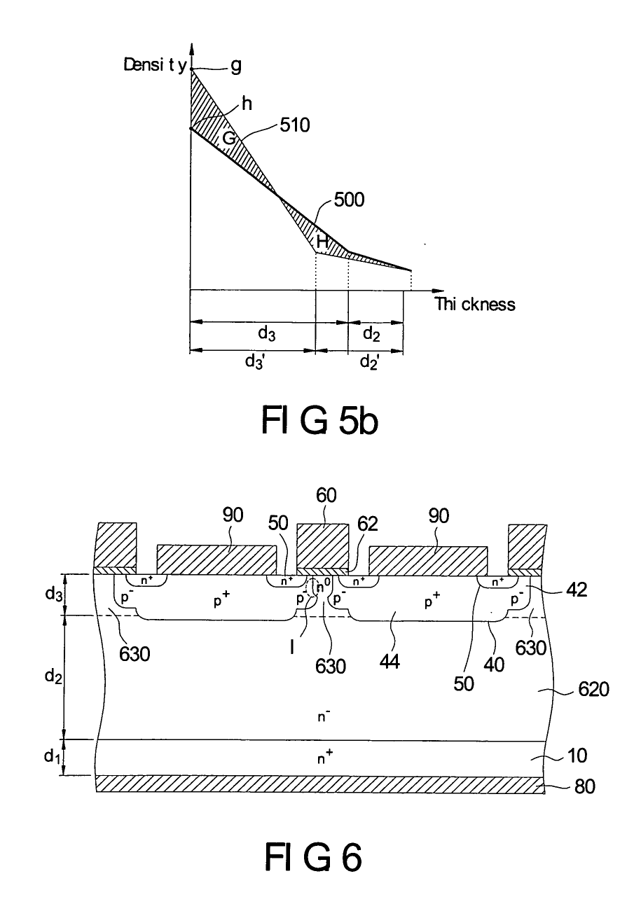

FIG. 6 illustrates a power MOSFET that has been produced using the conventional method of ion implantation and diffusion. Thicknesses of the epitaxial layer (620) and the JFET area (630) are d2 and d3, respectively. Legends for all other components also shown in FIG. 1 are maintained.

As aforementioned, the MOSFET produced using a conventional process positions the body's (40) outer edge (J) inwards. This is specifically because increased dose of n-type dopants are introduced to reduce resistance at the JFET (630): the p-type body area's (40) increased dopant dose the outer edge (J) turns to n-type, pushing-in the body area. And even if the body area does not shape as shown, its outer edge (J) comes to have lower impurity density than other sections under the conventional method. The further inward the outer edge (J) of the body area (40) is pushed, the greater the risk of punchthrough.

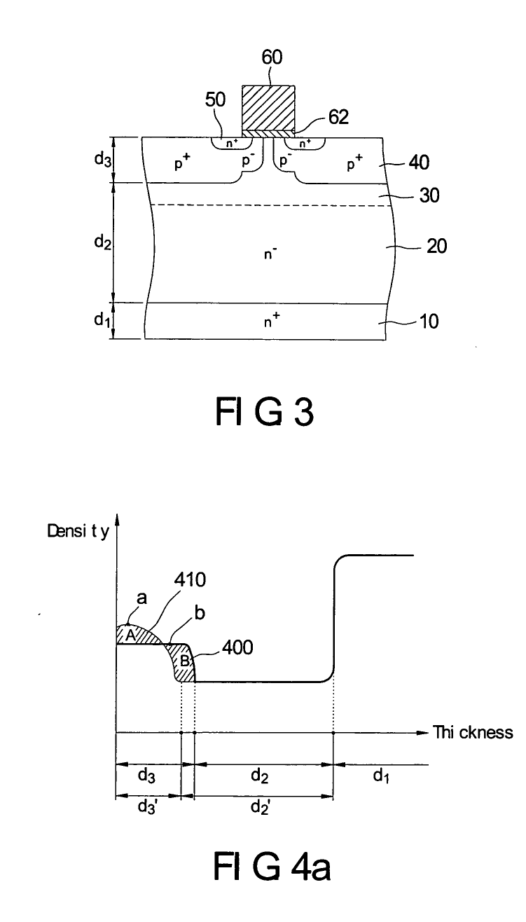

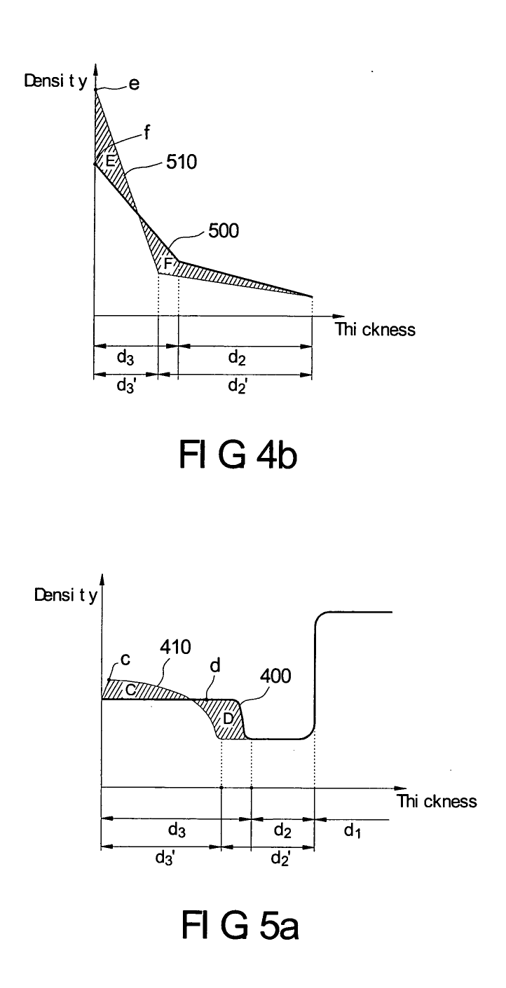

In the power MOSFET, as per this example, the JFET is grown not by ion implantation and diffusion, but rather via the epitaxial layer, eliminating deformations in the body area as shown in FIG. 6. The following describes how the invention solves this problem, referring to FIG. 4 and FIG. 5.

FIG. 4 (a) and FIG. 5 (a) are graphs that illustrate concentration distributions over depth in the practical application example of this invention and the conventional method, respectively. FIG. 4 (a) is with the JFET thinly formed, and FIG. 5 (a) is with the JFET thickly formed. The concentration distribution of this invention's practical application example is expressed in a solid line (400), whereas the concentration distribution of the conventional method is shown in a thin line (410). The graphs also include substrate thickness (d1), primary epitaxial thickness (d2, d2′), and secondary epitaxial and JFET thicknesses (d3, d3′).

Each of the graphs includes density and electric field profiles from this invention's practical application example and the conventional method. Referring to these profiles, the concentration distribution (400) of the power MOSFET designed as per the invention's practical application example is vastly different than the Gaussian distribution profile (410) produced by the conventional ion implantation and diffusion method. In respect to doping density, power MOSFETs with dual epitaxial layers as prescribed within exhibit a flat density profile (400) at the secondary epitaxial area (JFET), whereas power MOSFETs formed based on the conventional method of ion implantation and diffusion exhibit a Gaussian distribution density profile (410). This is because the epitaxial layers are formed layer by layer using a reaction gas of uniform density.

A flat density profile (400) in the secondary epitaxial area signifies that the maximum concentration value at this area is less compared with the conventional method. In the conventional method, body areas formed on the JFET contact the JFET with high concentration (depths marked by point A in FIG. 4 (a) and point C in FIG. 5 (a), causing the outer edge of the body area to partially change to n-type or lowering its concentration. In this invention, concentration of the p-type body area formed on the JFET is minimized to prevent deformation of the body areas and prevent the punchthrough effect. Although maintaining a uniform density profile at all depth levels throughout the JFET does increase the on-resistance at the upper end of the secondary epitaxial area, the increase is miniscule in comparison with the benefits gained.

The JFET thickness (d3) required for designing the MOSFET as per this invention can be derived as follows to match the on-resistance and breakdown voltage values to the values the conventional ion implantation and diffusion method would produce.

First, to match the on-resistance value of conventional MOSFETs, surface areas A and B must equal C and D (FIG. 4 (a) and FIG. 5 (a)), where A, B, C, and D each represent quantity of electric charge at the corresponding depth. Because on-resistance is proportionate to the quantity of electric charge, equal surface area equates to equal on-resistance. And because ion implantation and diffusion produces a Gaussian distribution profile (410) and a dual epitaxial area produces a concentration profile (400) that remains flat then decreases suddenly, the JFET in the semiconductor as per this invention possess deeper dimensions in order to match the quantity of electrical charge with the quantity delivered via the conventional method. Ergo, the thickness of the JFET (d3) in this invention is thicker than in the conventional method (d3′).

FIG. 4 (b) and FIG. 5 (b) illustrate the electrical field intensities of the two methods with an identical on-resistance value. FIG. 4 (b) illustrates electrical field intensity at the depth equivalent to the minuscule distribution in FIG. 4 (a), and FIG. 5 (b) illustrates electrical field intensity at the depth equivalent to the density distribution in FIG. 5 (a). Electrical field intensity for the semiconductor as per this device (500) is shown in a solid line, whereas electrical field intensity for the conventional method (510) is shown in a thin line.

As shown, the maximum electrical field intensity value (f) for the semiconductor as per this invention is lower than the conventional method (e), exhibiting a slow negative gradient. Area for E and F is equivalent to G and H in FIG. 4 (b) and FIG. 5 (b) since the JFET in the application example is thicker than in the conventional method. Equal area also indicates that the breakdown voltage for the two methods also equal. Since the electrical field intensity gradients in FIG. 4 (b) and FIG. 5 (b) are determined by the scale of concentration, and the product of electrical field intensity and thickness is the breakdown voltage, equal area values for E, F, G, and H invariably determines that the breakdown voltage values are also equal.

In conclusion, the power MOSFET as per this invention exhibits the same breakdown voltage and on-resistance values as the conventional method, while significantly lowering the risk of punchthrough in the channel area and allowing the design of a more reliable product.

Another advantage offered by the power MOSFET as per this invention is the free range of choice given to the designer in the area of JFET thickness and position, meaning that the thickness can be adjusted to control the semiconductor's on-resistance and breakdown voltage values.

Furthermore, the design presented in the invention greatly reduces the width of the gate electrode. This is because the design affords greater control precision in forming the body areas and thereby reduces the gap between the body areas. Narrower gate electrode width offers various advantages, including significant increase in the semiconductor's breakdown voltage and reduction of capacitance (Cgd) between the gate and drain. Here, capacitance is an important factor in reducing switching loss of the semiconductor.

Numerous, in-depth descriptions have been provided regarding this invention thus far; however, the invention should not be considered as limited within the boundaries of the practical application examples given.

[Effects of the Invention]

The maximum concentration value at the JFET in a power MOSFET as per this invention is lower than the maximum concentration value produced by the conventional ion implantation and diffusion method. Because of this, this invention is capable of forming p-type body areas with greater stability and under less influence from density changes thereby preventing punchthrough effect at the channel. In other words, the breakdown voltage and on-resistance values remain the same, while the possibility of punchthrough is greatly reduced, permitting the design of a more reliable product.

What is claimed is:

1. A Power semiconductor device for preventing punchthrough and manufacturing method thereof, comprising:
An anti-punchthrough power semiconductor possessing a high-concentration substrate area of conduction type 1;
A primary epitaxial area of conduction type 1, formed in low concentration on top of the substrate area;
A secondary epitaxial area of conduction type 1, formed in medium density on top of the primary epitaxial area and with a doping profile that is actually uniform over the thickness;
Multiple secondary body areas of conduction type 2, formed within the secondary epitaxial area; and
Two source areas of conduction type 1, formed in high density along two edges of the body areas.

2. The power semiconductor device as in claim 1, wherein the body areas consist of a high density primary body area; and a low density secondary body area formed along the outer edge of the primary body area.

3. The power semiconductor device as in claim 1, wherein conduction type 1 is n-type and conduction type 2 is p-type.

4. The power semiconductor device as in claim 1, wherein the body areas are also formed partially over the primary epitaxial area.

5. The power semiconductor device as in claim 1, wherein the power semiconductor is a power MOS field effect transistor.

6. The power semiconductor device as in claim 1, wherein gate dielectrics located on top of the second epitaxial area and between the body areas, gate electrodes that impress electrical voltage on the channel areas, source electrodes that electrically connect with the source areas, and drain electrodes that electrically connect with the drain areas are further included.

7. A Power semiconductor device for preventing punchthrough and manufacturing method thereof, comprising:
An anti-punchthrough power semiconductor manufacturing method consisting of a stage in which the high-concentration drain area of conduction type 1 is formed;
A stage in which the primary epitaxial area of conduction type 1 formed on top of the drain area is grown in low density using epitaxy;
A stage in which the secondary epitaxial area of conduction type 1, formed on top of the primary epitaxial area is grown in medium density using epitaxy;
A stage in which multiple body areas of conduction type 2 are formed within the secondary epitaxial area; and
A stage in which the two source areas of conduction type 1 are formed in high density along the two edges of the body areas.

8. The power semiconductor manufacturing method as in claim 7, wherein the stage in which the body areas are formed further includes a stage in which the high concentration primary body area is formed, and a stage in which the low-concentration secondary body area is formed along the outer edge of the primary body area.

9. The power semiconductor manufacturing method as in claim 7, wherein conduction type 1 is n-type and conduction type 2 is p-type.

10. The power semiconductor manufacturing method as in claim 6, wherein the stage in which the body areas are formed is also a stage in which the body areas are formed partially over the primary epitaxial area.

11. The power semiconductor manufacturing method as in claim 7, wherein the power semiconductor is a power MOS field effect transistor.

12. The power semiconductor manufacturing method as in claim 7, wherein a stage in which a gate dielectric and a gate electrode are formed on top of the secondary epitaxial area and between the body areas, a stage in which the source electrode that electrically connect with the source area is formed, and a stage in which the drain electrode that electrically connect with the drain area is formed is further included.
